(19) United States
(12) Patent Application Publication
(10) Pub. No.: US 2026/0371771 A1
(43) Pub. Date: Nov. 19, 2026

(54) PHOTONIC STRUCTURES INCLUDING MULTIPLE PHOTODETECTORS

(71) Applicant: GlobalFoundries U.S. Inc., Malta, NY (US)

(72) Inventors: Abdelsalam Aboketaf, Essex Junction, VT (US); Yusheng Bian, Ballston Lake, NY (US)

(21) Appl. No.: 19/211,501

(22) Filed: May 19, 2025

(51) Int. Cl. H10F 39/90; G02B 6/122; G02B 6/13; G02B 6/12

(52) U.S. Cl. CPC H10F 39/90; G02B 6/122; G02B 6/13; G02B 2006/1215

(57) ABSTRACT

Structures that include multiple photodetectors and methods of forming and using a structure that includes multiple photodetectors. The structure comprises a waveguide core, a first photodetector having a first responsivity, and a second photodetector coupled by the waveguide core to the first photodetector. The second photodetector has a second responsivity that is greater than the first responsivity.

### BACKGROUND

The disclosure relates to photonics chips and, more specifically, to photonic structures that include multiple photodetectors and methods of forming and using a structure that includes multiple photodetectors.

Photodetectors in photonic chips find use in many applications and systems including, but not limited to, data communication systems and data computation systems. A photonic chip includes a photonic integrated circuit consisting of photonic components, such as modulators, polarizers, and optical couplers, that are used to manipulate light received from a light source, such as an optical fiber or a laser.

A photodetector may be deployed in a photonic integrated circuit to convert light, which may be modulated as an optical signal, into an electrical signal. Testing structures may be used to determine performance parameters for a photodetector, such as detector efficiency parameters like absorption and residual light leakage indicating light that is lost and not converted. However, conventional testing structures may be unable to provide accurate determinations of photodetector performance parameters.

Improved photonic structures that include multiple photodetectors and methods of forming and using a structure that includes multiple photodetectors are needed.

### SUMMARY

In an embodiment of the invention, a structure comprises a waveguide core, a first photodetector having a first responsivity, and a second photodetector coupled by the waveguide core to the first photodetector. The second photodetector has a second responsivity that is greater than the first responsivity.

In an embodiment of the invention, a method comprises inputting an optical signal into a first photodetector and supplying a portion of the optical signal from the first photodetector to a second photodetector. The first photodetector has a first responsivity, and the second photodetector has a second responsivity that is greater than the first responsivity.

In an embodiment of the invention, a method comprises forming a first photodetector having a first responsivity and forming a second photodetector that is coupled by a waveguide core to the first photodetector. The second photodetector has a second responsivity that is greater than the first responsivity.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention. In the drawings, like reference numerals refer to like features in the various views.

FIG. 1 is a top view of a structure for an optical switching device at an initial fabrication stage of a processing method in accordance with embodiments of the invention.

FIG. 2 is a cross-sectional view of the structure taken generally along line 2-2 in FIG. 1.

FIG. 2A is a cross-sectional view of the structure taken generally along line 2A-2A in FIG. 1.

FIG. 2B is a cross-sectional view of the structure taken generally along line 2B-2B in FIG. 1.

FIGS. 3, 3A, 3B are cross-sectional views of the structure at a fabrication stage subsequent to FIGS. 1, 2, 2A, 2B.

FIG. 4 is a top view of a structure in accordance with alternative embodiments of the invention.

### DETAILED DESCRIPTION

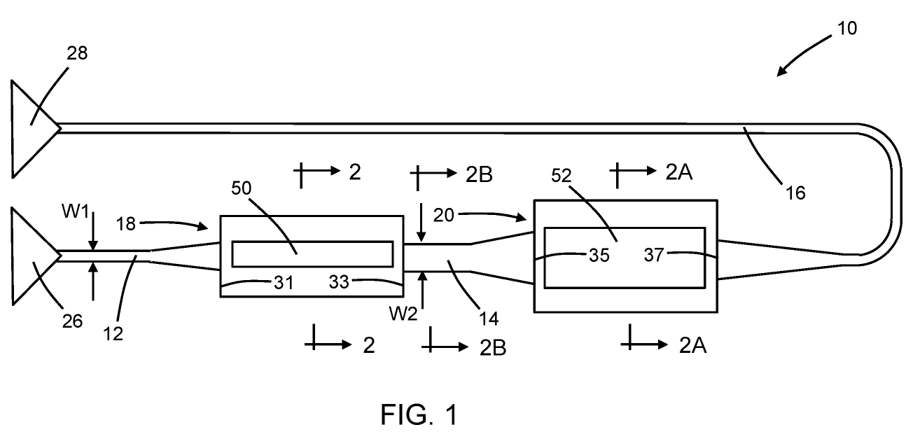

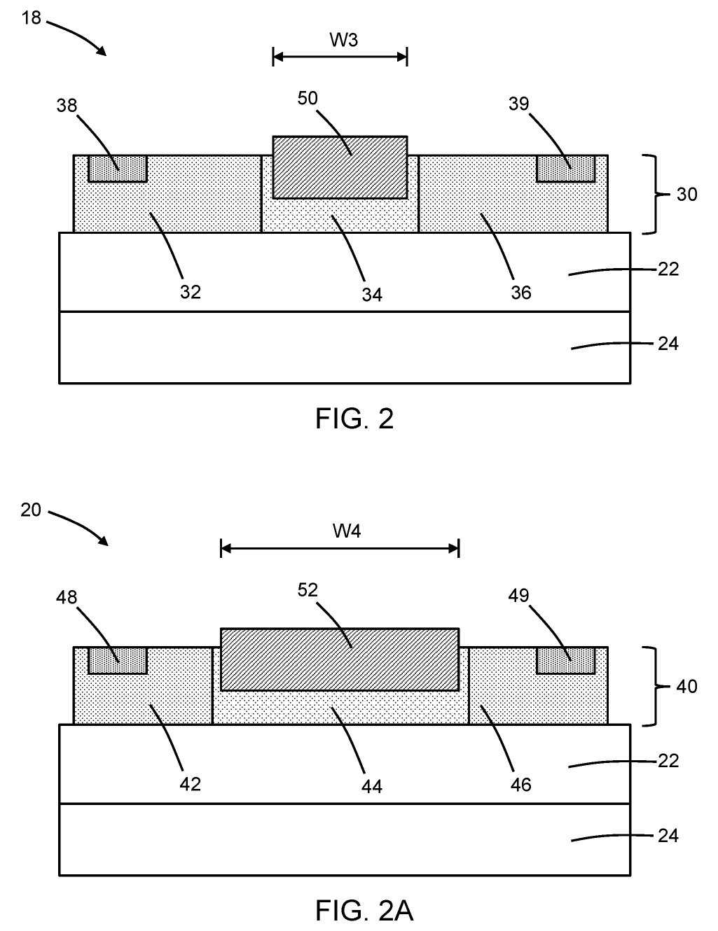

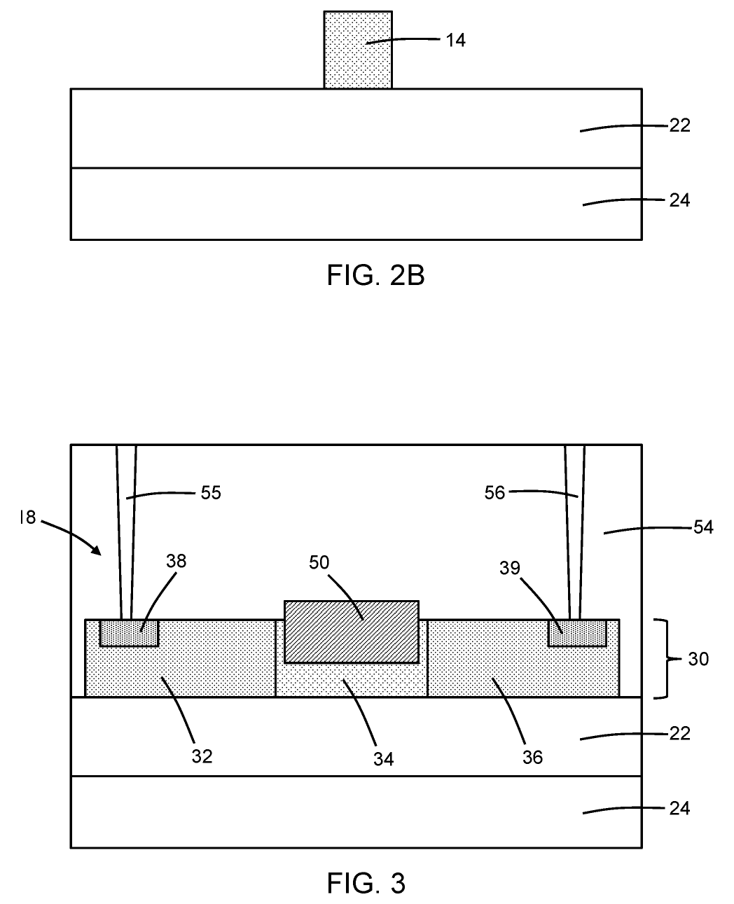

With reference to FIGS. 1, 2, 2A, 2B and in accordance with embodiments of the invention, a structure 10 includes a waveguide core 12, a waveguide core 14, a waveguide core 16, a photodetector 18, and a photodetector 20 that are positioned on, and overlie, a dielectric layer 22 and a semiconductor substrate 24. In an embodiment, the dielectric layer 22 may be comprised of a dielectric material, such as silicon oxide (e.g., silicon dioxide), and the semiconductor substrate 24 may be comprised of a semiconductor material, such as single-crystal silicon. In an embodiment, the dielectric layer 22 may be a buried oxide layer of a silicon-on-insulator substrate. The dielectric layer 22 is arranged in a vertical direction between the waveguide cores 12, 14, 16 and the semiconductor substrate 24, as well as in a vertical direction between the photodetectors 18, 20 and the semiconductor substrate 24. The dielectric layer 22 may provide low-index cladding for optical isolation from the semiconductor substrate 24.

The waveguide core 12 is routed from a receiver 26 to the photodetector 18 such that the waveguide core 12 connects the receiver 26 to the photodetector 18. The waveguide core 14 is routed from the photodetector 18 to the photodetector 20 such that the waveguide core 14 connects the photodetector 18 to the photodetector 20. The waveguide core 16 is routed from the photodetector 20 to a transmitter 28 such that the waveguide core 16 connects the photodetector 20 to the transmitter 28. In an embodiment, the receiver 26 and the transmitter 28 may be grating couplers.

The photodetector 18 includes a pad 30 that is positioned on the dielectric layer 22, and the photodetector 20 includes a pad 40 that is positioned on the dielectric layer 22. In an embodiment, the pad 30 and the pad 40 may be comprised of a material having a refractive index that is greater than the refractive index of silicon dioxide. In an embodiment, the pad 30 and the pad 40 may be comprised of a semiconductor material. In an embodiment, the pad 30 and the pad 40 may be comprised of single-crystal silicon. The pad 30 and the pad 40 may be formed by patterning a layer comprised of semiconductor material with lithography and etching processes. In an embodiment, the pad 30 and the pad 40 may be formed by patterning the semiconductor material, which may be single-crystal silicon, of the device layer of a silicon-on-insulator substrate.

The waveguide core 12 may have a width dimension W1, which may taper up (i.e., increase) over a portion of its length to adjoin a side edge 31 of the pad 30. The waveguide core 14 may have a width dimension W2 and may adjoin a side edge 33 of the pad 30 opposite from the side edge 31 adjoined by the waveguide core 12. The width dimension W2 of the waveguide core 14 may taper up over a portion of its length to adjoin a side edge 35 of the pad 40. The waveguide core 14 may extend from the side edge 33 of the pad 30 to the side edge 35 of the pad 40. The waveguide core 16 may adjoin a side edge 37 of the pad 40 opposite from the side edge 35 adjoined by the waveguide core 14 and may extend from the pad 40 to the transmitter 28.

The pad 30 may include a doped region 32, an undoped region 34, and a doped region 36. The undoped region 34 is arranged in a lateral direction between the doped region 32 and the doped region 36. The semiconductor material of the doped region 32 may have an opposite conductivity type from the semiconductor material of the doped region 36. The undoped region 34 is comprised of intrinsic semiconductor material.

The pad 40 may include a doped region 42, an undoped region 44, and a doped region 46. The undoped region 44 is arranged in a lateral direction between the doped region 42 and the doped region 46. The semiconductor material of the doped region 42 may have an opposite conductivity type from the semiconductor material of the doped region 46. The undoped region 44 is comprised of intrinsic semiconductor material.

The doped regions 32, 42 may be formed by, for example, ion implantation with an implantation mask having openings that determine respective implanted areas of the pads 30, 40. The implantation mask may include a layer of photoresist applied by a spin-coating process, pre-baked, exposed to light projected through a photomask, baked after exposure, and developed with a chemical developer to define the openings over the areas of the pads 30, 40 to be implanted. The implantation conditions, such as ion species, dose, and kinetic energy, may be selected to tune the electrical and physical characteristics of the doped regions 32, 42. The implantation mask may be stripped after forming the doped regions 32, 42. In an embodiment, the semiconductor material of the doped regions 32, 42 may contain an n-type dopant, such as arsenic or phosphorus, that provides n-type electrical conductivity.

The doped regions 36, 46 may be formed by, for example, ion implantation with an implantation mask having openings that determine respective implanted areas of the pads 30, 40. The implantation mask may include a layer of photoresist applied by a spin-coating process, pre-baked, exposed to light projected through a photomask, baked after exposure, and developed with a chemical developer to define the openings over the areas of the pads 30, 40 to be implanted. The implantation conditions, such as ion species, dose, and kinetic energy, may be selected to tune the electrical and physical characteristics of the doped regions 36, 46. The implantation mask may be stripped after forming the doped regions 36, 46. In an embodiment, the semiconductor material of the doped regions 36, 46 may contain a p-type dopant, such as boron, that provides p-type electrical conductivity.

Doped regions 38, 48 may be formed by a masked ion implantation in respective portions of the doped regions 32, 42. The doped regions 38, 48 may have the same conductivity type (e.g., n-type) as the doped regions 32, 42 but at a higher dopant concentration. Doped regions 39, 49 may be formed by a masked ion implantation in respective portions of the doped regions 36, 46. The doped regions 39, 49 may have the same conductivity type (e.g., p-type) as the doped regions 36, 46 but at a higher dopant concentration.

The photodetector 18 further includes a semiconductor layer 50 representing a light-absorbing region that may be formed in a recess patterned by lithography and etching processes in the pad 30. The photodetector 20 further includes a semiconductor layer 52 representing a light-absorbing region that may be formed in a recess patterned by lithography and etching processes in the pad 40. In an embodiment, the semiconductor layer 52 may be larger in size than the semiconductor layer 50. In an embodiment, the semiconductor layer 50 may have a width dimension W3, and the semiconductor layer 52 may have a width dimension W4 that is greater than the width dimension W3. The larger size (e.g., width dimension) of the semiconductor layer 52 provides the photodetector 20 with a higher responsiveness than the photodetector 18.

The semiconductor layer 50 of the photodetector 18 and the semiconductor layer 52 of the photodetector 20 may be comprised of a light-absorbing material that is configured to absorb light of a given wavelength, such as a wavelength within an infrared wavelength band of the electromagnetic spectrum, and to generate charge carriers from photons of the absorbed light by photoelectric conversion. In an embodiment, the semiconductor layers 50, 52 may be comprised of a different material from the pads 30, 40. In an embodiment, the semiconductor layers 50, 52 may be comprised of a material having a composition that includes germanium. In an embodiment, the semiconductor layers 50, 52 may be comprised of intrinsic germanium that is undoped. In an alternative embodiment, the semiconductor layers 50, 52 may be comprised of a III-V compound semiconductor material. In an alternative embodiment, the semiconductor layers 50, 52 may be comprised of intrinsic silicon.

In an embodiment, the doped regions 32, 36 may be laterally spaced from the semiconductor layer 50 such that the semiconductor layer 50 has a non-overlapping relationship with the doped regions 32, 36 and portions of the undoped region 34 are arranged between the semiconductor layer 50 and the doped regions 32, 36. In an embodiment, the doped regions 42, 46 may be laterally spaced from the semiconductor layer 52 such that the semiconductor layer 52 has a non-overlapping relationship with the doped regions 42, 46 and portions of the undoped region 44 are arranged between the semiconductor layer 52 and the doped regions 42, 46.

In an alternative embodiment, the photodetectors 18, 20 may be configured as lateral avalanche photodetectors that further integrate a multiplication layer and a charge layer. In an alternative embodiment, the photodetectors 18, 20 may have a vertical arrangement instead of a lateral arrangement. Specifically, the photodetectors 18, 20 may be configured as vertical photodetectors or as vertical avalanche photodetectors.

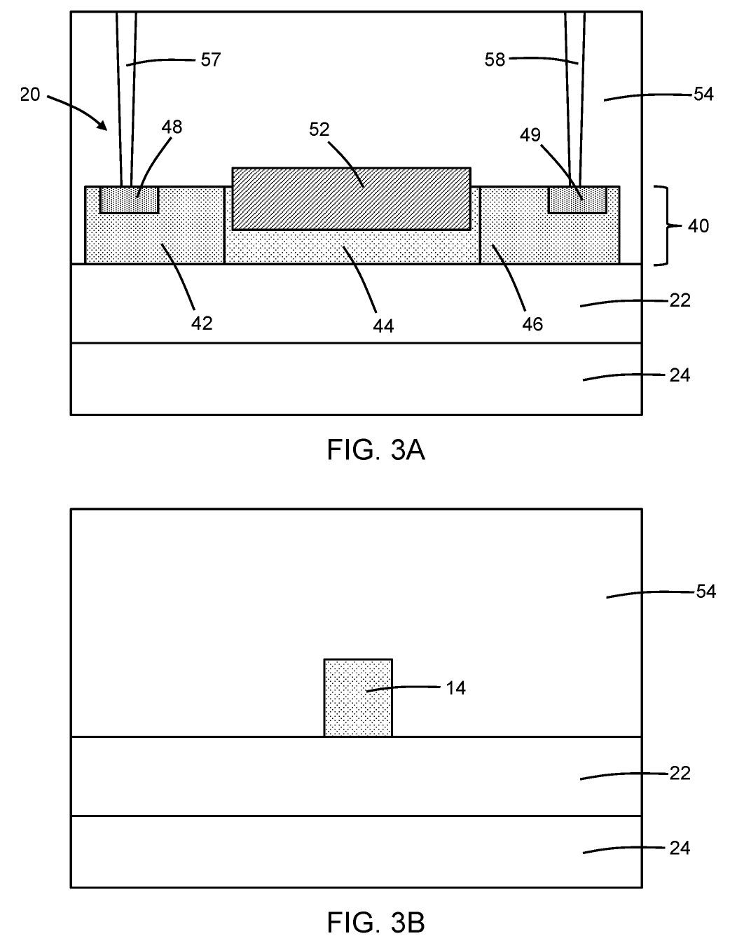

With reference to FIGS. 3, 3A, 3B in which like reference numerals refer to like features in FIGS. 1, 2, 2A, 2B and at a subsequent fabrication stage, a dielectric layer 54 may be formed over the waveguide cores 12, 14, 16 and photodetectors 18, 20. The dielectric layer 54 may be comprised of a dielectric material, such as silicon oxide (e.g., silicon dioxide), having a lower refractive index than the materials constituting the waveguide cores 12, 14, 16.

Contacts 55 may be formed in the dielectric layer 54 that are coupled by the doped region 38 to the doped region 32, and contacts 56 may be formed in the dielectric layer 54 that are coupled by the doped region 39 to the doped region 36. Contacts 57 may be formed in the dielectric layer 54 that are coupled by the doped region 48 to the doped region 42, and contacts 58 may be formed in the dielectric layer 54 that are coupled by the doped region 49 to the doped region 46. The contacts 55, 56 and the contacts 57, 58 may be comprised of a metal, such as tungsten. The contacts 55, 56 may be used to supply a bias voltage to the photodetector 18 and to thereby collect charge carriers during operation of the photodetector 18. The contacts 57, 58 may be used to supply a bias voltage to the photodetector 20 and to thereby collect charge carriers during operation of the photodetector 20.

In use, an optical signal may be routed by the waveguide core 12 from the receiver 26 as input to the photodetector 18. A portion of the light received from the waveguide core 12 is absorbed by the semiconductor layer 50 and a photocurrent is collected as output from the photodetector 18 under the biasing applied via the contacts 55, 56. A portion of the light received from the waveguide core 12 is not absorbed by the semiconductor layer 50. The unabsorbed portion of the light exits the semiconductor layer 50 and is routed by the waveguide core 14 to the photodetector 20. A portion of the light received from the waveguide core 14 is absorbed by the semiconductor layer 52 and a photocurrent is collected as output from the photodetector 20 under the biasing applied via the contacts 57, 58. An unabsorbed portion of the light may exit the semiconductor layer 52 and may be routed by the waveguide core 16 to the transmitter 28.

The photodetector 20 may be used to determine performance parameters for the photodetector 18, which may be considered to be a device under test. For example, the output from the photodetector 20 may be used to determine detector efficiency parameters, such as absorption and residual light leakage, for the photodetector 18. The structure 10 may be deployed on either a test chip for performance determination or on a production chip as a performance monitor.

The photodetector 18 may be characterized by a responsivity, and the photodetector 20 may be characterized by a responsivity that is greater than the responsivity of the photodetector 18. The responsivity of a photodetector is a measure of the electrical output per optical input and may be expressed in units of amperes per watt of incident radiant power. In an embodiment, the photodetector 20 may have a responsivity in a range of about 0.7 amperes per watt to about 0.9 amperes per watt, and the photodetector 18 may have a responsivity that is less than 0.7 amperes per watt. In an embodiment, the photodetector 20 may have a responsivity of about 1 ampere per watt, and the photodetector 18 may have a responsivity that is less than the responsivity of the photodetector 20. Alternatively, the photodetector 18 may be characterized by a quantum efficiency, and the photodetector 20 may be characterized by a quantum efficiency that is greater than the quantum efficiency of the photodetector 18. The quantum efficiency of a photodetector is a measure of the ratio of generated charge carriers to incident photons and is dimensionless. A high responsivity, or quantum efficiency, permits the photodetector 20 to accurately determine performance parameters for the photodetector 18.

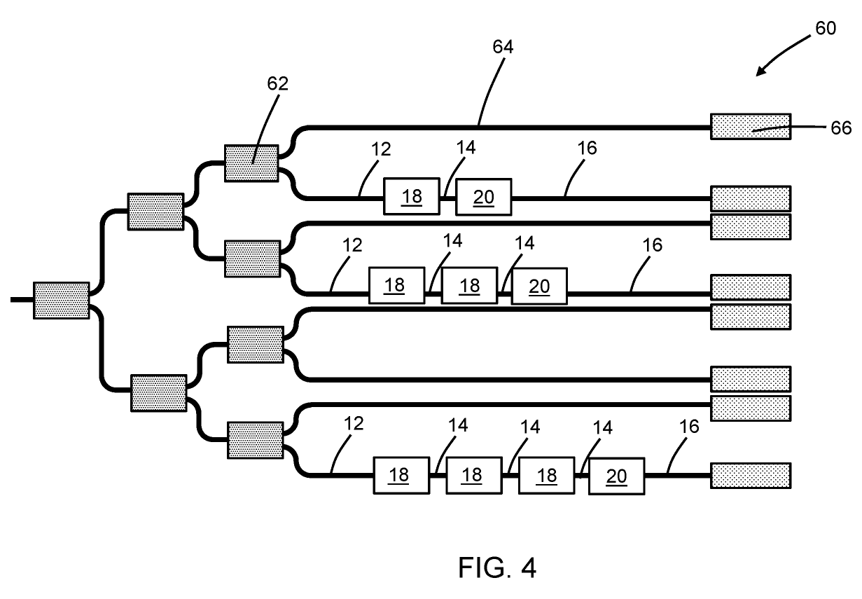

With reference to FIG. 4 and in accordance with alternative embodiments of the invention, multiple instances of the photodetectors 18, 20 may be arranged in a structure 60. An input signal from a receiver, such as a grating coupler or an edge coupler, may be split by a network of optical splitters 62, which may be multimode interference splitters, into multiple optical paths 64 that end at absorbers 66. Some of the optical paths 64 lack instances of either of the photodetectors 18, 20.

One optical path 64 has a configuration that includes a single instance of the photodetector 18 that is coupled to a single instance of the photodetector 20, and the photodetector 18 is arranged in the optical path 64 between one of the optical splitters 62 and the photodetector 20. Another optical path 64 has a configuration that includes a pair of instances of the photodetector 18 that are arranged in series and that are coupled to a single instance of the photodetector 20, and the pair of instances of the photodetector 18 is arranged in the optical path 64 between one of the optical splitters 62 and the photodetector 20. Another optical path 64 has a configuration that includes a trio of instances of the photodetector 18 that are arranged in series and that are coupled to a single instance of the photodetector 20, and the trio of instances of the photodetectors 18 is arranged in the optical path 64 between one of the optical splitters 62 and the photodetector 20. In each configuration, the photodetectors 18, 20 are cascaded such that the photodetector 20 is positioned in each optical path 64 to detect an unabsorbed portion of the input light.

The arrangement of the photodetectors 18, 20 in the structure 10 may be used to perform efficiency measurements characterized by a reduced noise background, which may improve the accuracy of the measurements. For example, a linear regression analysis may be used to provide the efficiency measurements of the photodetector 18. In an embodiment, all of the photodetectors 18 in the structure 60 may be characterized by the same responsivity. In an embodiment, all of the photodetectors 20 in the structure 60 may be characterized by the same responsivity. In an embodiment, all of the photodetectors 18 may be characterized by the same responsivity and all of the photodetectors 20 in the structure 60 may be characterized by the same responsivity.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. The chip may be integrated with other chips, discrete circuit elements, and/or other signal processing devices as part of either an intermediate product or an end product. The end product can be any product that includes integrated circuit chips, such as computer products having a central processor or smartphones.

References herein to terms modified by language of approximation, such as “about”, “approximately”, and “substantially”, are not to be limited to the precise value or precise condition as specified. In embodiments, language of approximation may indicate a range of +/- 10% of the stated value(s) or the stated condition(s).

References herein to terms such as “vertical”, “horizontal”, etc. are made by way of example, and not by way of limitation, to establish a frame of reference. The term “horizontal” as used herein is defined as a plane parallel to a conventional plane of a semiconductor substrate, regardless of its actual three-dimensional spatial orientation. The terms “vertical” and “normal” refer to a direction or plane in the frame of reference perpendicular to the horizontal plane, as just defined. The term “lateral” refers to a direction in the frame of reference within the horizontal plane.

A feature “connected” or “coupled” to or with another feature may be directly connected or coupled to or with the other feature or, instead, one or more intervening features may be present. A feature may be “directly connected” or “directly coupled” to or with another feature if intervening features are absent. A feature may be “indirectly connected” or “indirectly coupled” to or with another feature if at least one intervening feature is present. A feature “on” or “contacting” another feature may be directly on or in direct contact with the other feature or, instead, one or more intervening features may be present. A feature may be “directly on” or “directly contacting” another feature if intervening features are absent. A feature may be “indirectly on” or in “indirect contact” with another feature if at least one intervening feature is present. A feature may “overlie” another feature if a feature is positioned “over” another feature. Different features may “overlap” if a feature extends over, and covers a part of, another feature.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure comprising:
a first waveguide core;
a first photodetector having a first responsivity; and
a second photodetector coupled by the first waveguide core to the first photodetector, the second photodetector having a second responsivity that is greater than the first responsivity.

2. The structure of claim 1 wherein the first photodetector includes a first semiconductor layer comprising a first semiconductor material configured to absorb light and to generate charge carriers, and the second photodetector includes a second semiconductor layer comprising a second semiconductor material configured to absorb light and to generate charge carriers.

3. The structure of claim 2 wherein the first semiconductor layer has a first size, and the second semiconductor layer has a second size that is larger than the first size of the first semiconductor layer.

4. The structure of claim 2 wherein the first semiconductor layer has a first width dimension, and the second semiconductor layer has a second width dimension that is greater than the first width dimension of the first semiconductor layer.

5. The structure of claim 3 wherein the first semiconductor material and the second semiconductor material comprise germanium.

6. The structure of claim 2 wherein the second photodetector includes a pad, a first doped region in the pad, and a second doped region in the pad, the first doped region and the second doped region have opposite conductivity types, and the second semiconductor layer is laterally arranged between the first doped region and the second doped region with a non-overlapping relationship.

7. The structure of claim 1 wherein the second responsivity of the second photodetector ranges from about 0.7 amperes per watt to about 0.9 amperes per watt.

8. The structure of claim 1 wherein the second responsivity of the second photodetector about 1 ampere per watt.

9. The structure of claim 1 wherein the first photodetector includes a first pad having a first side edge, the second photodetector includes a second pad having a side edge, and the first waveguide core couples the first side edge of the first pad to the side edge of the second pad.

10. The structure of claim 9 wherein the first pad of the first photodetector has a second side edge opposite from the first side edge, and further comprising:
a second waveguide core coupled to the second side edge of the first pad,
wherein the second waveguide core is configured to supply an input optical signal to the first photodetector.

11. The structure of claim 10 wherein the first photodetector includes a semiconductor layer comprising a semiconductor material configured to absorb light and to generate charge carriers, and the semiconductor layer is positioned between the first side edge and the second side edge.

12. The structure of claim 9 wherein the first pad of the first photodetector has a second side edge opposite from the first side edge, and further comprising:
a second waveguide core; and
a third photodetector coupled by the second waveguide core to the second side edge of the first pad.

13. The structure of claim 12 wherein the third photodetector has the first responsivity.

14. The structure of claim 1 further comprising:
a second waveguide core; and
a third photodetector coupled by the second waveguide core to the first photodetector.

15. The structure of claim 14 wherein the third photodetector has the first responsivity.

16. The structure of claim 1 further comprising:
a first optical path including the first photodetector, the second photodetector, and the first waveguide core; and
a second optical path including a second waveguide core, a third photodetector having the first responsivity, and a fourth photodetector having the second responsivity, and the fourth photodetector coupled by the second waveguide core to the third photodetector.

17. The structure of claim 16 further comprising:
a plurality of optical splitters coupled to the first optical path and the second optical path.

18. The structure of claim 17 wherein the first photodetector is arranged in the first optical path between the second photodetector and one of the plurality of optical splitters.

19. A method comprising:
inputting an optical signal into a first photodetector; and
supplying a portion of the optical signal from the first photodetector to a second photodetector,
wherein the first photodetector has a first responsivity, and the second photodetector has a second responsivity that is greater than the first responsivity.

20. A method comprising:
forming a first photodetector having a first responsivity; and
forming a second photodetector that is coupled by a waveguide core to the first photodetector,
wherein the second photodetector has a second responsivity that is greater than the first responsivity.
